(19) United States
(12) Patent Application Publication
(10) Pub. No.: US 2026/0190412 A1
(43) Pub. Date: Jul. 2, 2026

(54) METHOD FOR MANUFACTURING SEMI-FLOATING GATE TRANSISTOR

(71) Applicant: Shanghai Huali Integrated Circuit Coproration, Shanghai (CN)

(72) Inventors: Shiling Yang, Shanghai (CN); Yanfei Ma, Shanghai (CN)

(73) Assignee: Shanghai Huali Integrated Circuit Coproration, Shanghai (CN)

(21) Appl. No.: 19/280,618

(22) Filed: Jul. 25, 2025

(30) Foreign Application Priority Data
Jan. 2, 2025 (CN) 202510008696.0

(51) Int. Cl. H10D 64/01; H10P 50/00

(52) U.S. Cl. CPC H10D 64/01306; H10D 64/01324; H10D 64/01328; H10P 50/71

(57) ABSTRACT

The present disclosure discloses a method for manufacturing a semi-floating gate transistor. Self-aligned etching is performed by using an SIN protection layer of a control gate structure to form a vertical contact window, instead of the photolithography and etching of conventional lateral contact window, thus omitting one contact window photolithography process, avoiding the formation of an asymmetric semi-floating gate device due to the deterioration of the photolithography pattern overlay of the lateral contact window, and greatly improving the uniformity and the process window of the semi-floating gate transistor. In addition, since the physical distance between the vertical contact window and the gate of the tunnel field-effect transistor of the semi-floating gate transistor is significantly shortened, the tunneling efficiency is high, thus improving the charging speed of the semi-floating gate polysilicon.

### CROSS-REFERENCE TO RELATED APPLICATIONS

This application claims priority to Chinese patent application No. 202510008696.0, filed on January 2, 2025, the disclosure of which is incorporated herein by reference in its entirety.

### TECHNICAL FIELD

The present disclosure relates to the field of semiconductor manufacturing, and in particular to a method for manufacturing a Semi-Floating Gate Transistor (SFGT).

### BACKGROUND

Capacitors have been a bottleneck in the development of conventional Dynamic Random Access Memories (DRAMs). As a promising capacitor-less DRAM solution, the Semi-Floating Gate Transistor (SFGT) is compatible with standard logic processes and is more easily miniaturized. As shown in FIG. 1, the Semi-Floating Gate Transistor (SFGT) is a novel "semi-floating gate" structured device that integrates a Tunnel Field-Effect Transistor (TFET) with a floating gate device. The TFET handles charging/discharging of the floating gate to perform “data erasure/writing” operations, while the floating gate manages “data storage and readout” functions. Semi-Floating Gate Transistor (SFGT) makes data erasure easier and faster.

The U-shaped trench (U-trench) in the floating gate device can electrically isolate the semi-floating gate N-well (Nwell), while its bottom forms a U-shaped channel. Compared to channels with conventional profiles, this structure helps to scale down the device area. In addition, the gate polysilicon in the U-shaped trench is used for storing charges and utilizing the tunneling effect to accelerate charge writing.

P-type doped semi-floating gate polysilicon forms a PN junction by directly contacting a N-type doped semi-floating gate N-well (Nwell) on a silicon substrate through a semi-floating gate dielectric contact window (C-window) on a gate oxide (gate OX) of the U-shaped trench (U-trench). The charging and discharging process of the semi-floating gate polysilicon is a process of charges entering and exiting the semi-floating gate dielectric contact window (C-window), thus achieving the transition between device logic 1 and 0 states.

In an embedded logic/memory-compatible semi-floating gate process, after formation of a U-shaped trench, a semi-floating gate dielectric layer is grown, then first deposition of semi-floating gate polysilicon is performed to fill the U-shaped trench, then a semi-floating gate dielectric on an upper surface of the semi-floating gate N-well on one side of the U-shaped trench is etched to form a semi-floating gate dielectric contact window (C-window) and expose the upper surface of the semi-floating gate N-well of the silicon substrate, then second deposition of the semi-floating gate polysilicon is performed, P-type doping is performed to achieve contact between the semi-floating gate polysilicon and the semi-floating gate N-well of the silicon substrate, the thickness of the semi-floating gate polysilicon above the silicon substrate is reduced (thinned to approximately 110Å) through etching, then a control gate dielectric layer is grown, and control gate polysilicon is deposited, and a self-aligned control gate/semi-floating gate pattern is formed through control gate photolithography and etching processes.

In the embedded logic/memory-compatible semi-floating gate process, the PN junction formed by contact between the semi-floating gate polysilicon and a substrate active area at the semi-floating gate dielectric contact window (C-window) is a functional core of the semi-floating gate operation. Since photolithography and etching are adopted to define a C-window region, forming a lateral contact window (C-window), pattern overlay accuracy along an Active Area (AA) direction critically influences device performance. Under an ideal photolithography pattern overlay (PH overlay) condition for the contact window (C-window), a symmetric semi-floating gate device is formed. However, a deteriorated photolithography pattern overlay (PH overlay) condition for the contact window (C-window), an asymmetric semi-floating gate device is formed.

The ideal photolithography pattern overlay (PH overlay) condition for the contact window (C-window) is as shown in FIG. 2, under which the symmetric semi-floating gate device is formed.

The deteriorated photolithography pattern overlay (PH overlay) condition for the contact window (C-window) is as shown in FIG. 3, under which the asymmetric semi-floating gate device is formed, where for the semi-floating device on a left side of the semi-floating gate dielectric contact window (C-window), since the opening of the contact window (C-window) is small, the contact window (C-window) is far away from the gate of the Tunnel Field-Effect Transistor (TFET), the tunneling efficiency is low and speed of injecting charges into the semi-floating gate polysilicon is slow; for the semi-floating gate device on a right side, since the opening of the contact window (C-window) is too large, in a case that the control gate photolithography overlay (control gate PH OVL) is poor, the exposed silicon substrate will be damaged during control gate pattern etching, causing void defects.

### BRIEF SUMMARY

A method for manufacturing the semi-floating gate transistor provided in the present disclosure includes the following steps:

S1: providing a semiconductor silicon substrate 100, where

in a first region 103 of the semiconductor silicon substrate 100, the semiconductor silicon substrate 100 is isolated by multiple strips of X-direction field oxides 101 into multiple strips of X-direction first active areas 105, and the multiple strips of X-direction field oxides 101 and the multiple strips of X-direction first active areas 105 are arranged in parallel;

an X direction is a direction parallel to a length direction of the first active areas, and a Y direction is perpendicular to the X direction;

opening the first region 103 to expose upper surfaces of the X-direction field oxides 101 and upper surfaces of the first active areas 105 in the first region 103;

performing photolithography and etching to form a U-shaped trench 109 in each first active area 105 along multiple pairs of Y-direction openings, where

each pair of Y-direction openings is composed of adjacent two Y-direction openings along the X direction; and

forming a trench oxide layer 110 on the upper surfaces of the first active areas 105 and surfaces of the U-shaped trenches 109;

S2: depositing semi-floating gate polysilicon 120, where the U-shaped trenches 109 are filled with the semi-floating gate polysilicon 120;

S3: performing photolithography and etching to remove the semi-floating gate polysilicon 120 on the X-direction field oxides 101;

S4: depositing a gate oxide layer 121;

S5: depositing control gate polysilicon 122;

S6: depositing an SIN hard mask 123;

S7: performing photolithography and etching to remove the SIN hard mask 123 and the control gate polysilicon outside a set width on an X-direction outer side of each pair of Y-direction openings, stop at the gate oxide layer 121, and reserve the SIN hard mask 123 and the control gate polysilicon 122 between each pair of Y-direction openings and within the set width on the X-direction outer side thereof;

S8: depositing an SIN sidewall dielectric layer 124;

S9: etching the SIN sidewall dielectric layer 124 to remove the SIN sidewall dielectric layer 124 above the control gate polysilicon 122 corresponding to each pair of Y-direction openings, remove the SIN sidewall dielectric layer 124 above the gate oxide layer 121 on an X-direction outer side of the control gate polysilicon 122 corresponding to each pair of Y-direction openings, and form a control gate sidewall;

S10: performing self-aligned etching on the trench oxide layer 110 by using the SIN hard mask 123 and the control gate sidewall as a mask to remove the gate oxide layer 121, the semi-floating gate polysilicon 120, and the trench oxide layer 110 on the X-direction outer side of the control gate polysilicon 122 corresponding to each pair of Y-direction openings, and expose the X-direction outer side of the semi-floating gate polysilicon 120 corresponding to each pair of Y-direction openings as a contact window 111;

S11: growing a silicon epitaxy 125 on the upper surfaces of the exposed first active areas 105 and at the contact window 111 of the semi-floating gate polysilicon 120; and

S12: performing subsequent processes.

In some embodiments, in step S12, performing subsequent processes includes removing the SIN hard mask 123 and the SIN sidewall dielectric layer 124.

In some embodiments, the semiconductor silicon substrate 100 further includes a second region 104;

the first region 103 and the second region 104 are separated by shallow trench isolation 102;

the first region 103 is used for forming a memory cell array;

the second region 104 is used for forming a logic circuit.

In some embodiments, in step S2, the semi-floating gate polysilicon 120 is deposited firstly, and then blanket etching is performed to thin the semi-floating gate polysilicon 120 to a required height of a top surface of a semi-floating gate polysilicon.

In some embodiments, in step S11, residual oxides on the surfaces of the first active areas 105 on the X-direction outer side of the semi-floating gate polysilicon 120 corresponding to each pair of Y-direction openings are removed firstly, and then the silicon epitaxy 125 is grown on the upper surfaces of the exposed first active areas 105 and the contact window 111 of the semi-floating gate polysilicon 120.

In some embodiments, in step S11, the upper surface of the grown silicon epitaxy 125 is in flush with the upper surface of the semi-floating gate polysilicon 120.

In some embodiments, the set width is 1 to 3 times the thickness of the trench oxide layer 110.

In some embodiments, the set width ranges from 10nm to 80nm.

In some embodiments, in step S1, upper portions of the first active areas 105 undergo first-type doping and lower portions undergo second-type doping;

bottoms of the U-shaped trenches 109 enter the lower portions of the first active areas 105;

in step S2, the semi-floating gate polysilicon 120 undergoes the second-type doping;

the first-type doping is N-type doping, and the second-type doping is P-type doping; or, the first-type doping is P-type doping, and the second-type doping is N-type doping.

In the method for manufacturing the Semi-Floating Gate Transistor (SFGT) provided in the present disclosure, the photolithography and etching of the lateral contact window (C-window) are directly omitted, thus simplifying the existing two semi-floating gate polysilicon deposition processes into one; the SIN hard mask 123 is deposited on the control gate polysilicon 122, then photolithography is performed to define the control gate structure pattern, the control gate polysilicon 122 and the SIN hard mask 123 are etched, etching is stopped on the gate oxide layer 121 on the upper surface of the semi-floating gate polysilicon 120 to form the control gate structure, and then the SIN sidewall of the control gate structure is formed. Since the top of the formed control gate structure is protected by the SIN hard mask 123 and the side surface is protected by the SIN sidewall, the control gate structure is completely protected by the SIN, so that subsequently self-aligned etching can be performed on the semi-floating gate polysilicon 120 by using the SIN as a hard mask, thus forming two semi-floating gate polysilicon side notches on the X-direction outer side of each pair of Y-direction openings corresponding to the semi-floating gate polysilicon 120, which is the self-aligned vertical contact window (C-window) 111. In the method for manufacturing the Semi-Floating Gate Transistor (SFGT), self-aligned etching is performed by using the mask for the photolithography of the control gate structure and using the SIN protection layer of the control gate structure to form the vertical contact window (C-window) 111，instead of the photolithography and etching of conventional lateral contact window (C-window), thus omitting one contact window (C-window) photolithography process, avoiding the formation of the asymmetric semi-floating gate device due to the deterioration of the photolithography pattern overlay (PH overlay) of the lateral contact window (C-window), and greatly improving the uniformity and the process window of the Semi-Floating Gate Transistor (SFGT). In addition, since the physical distance between the vertical contact window (C-window) 11 and the gate of the tunnel field-effect transistor (TFET) of the Semi-Floating Gate Transistor (SFGT) is significantly shortened, the tunneling efficiency is high, thus improving the charging speed of the semi-floating gate polysilicon.

### BRIEF DESCRIPTION OF THE DRAWINGS

In order to more clearly describe the technical solutions in the present disclosure, the following will briefly introduce the drawings needed in the present disclosure. It is obvious that the drawings in the following description are only some embodiments of the present disclosure. Those skilled in the art may obtain other drawings from these drawings without contributing any inventive labor.

FIG. 1 is a schematic diagram of a typical structure of a semi-floating gate transistor;

FIG. 2 is a schematic diagram of a symmetric semi-floating gate device formed by adopting an existing method for manufacturing a semi-floating gate transistor under an ideal photolithography pattern overlay condition for a contact window;

FIG. 3 is a schematic diagram of an asymmetric semi-floating gate device formed by adopting an existing method for manufacturing a semi-floating gate transistor under a deteriorated photolithography pattern overlay condition for a contact window; and

FIG. 4 to FIG. 15 are schematic diagrams of stereoscopic structures in each process step of a method for manufacturing a semi-floating gate transistor according to the present disclosure.

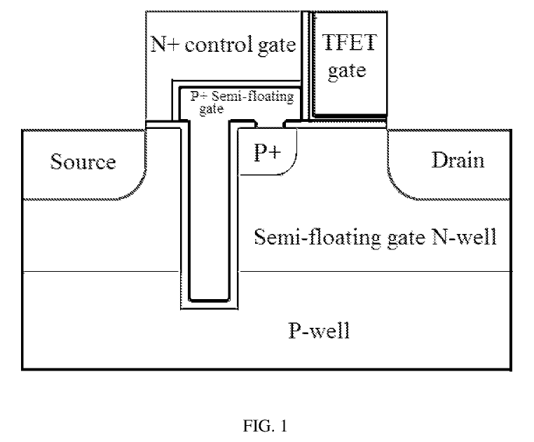

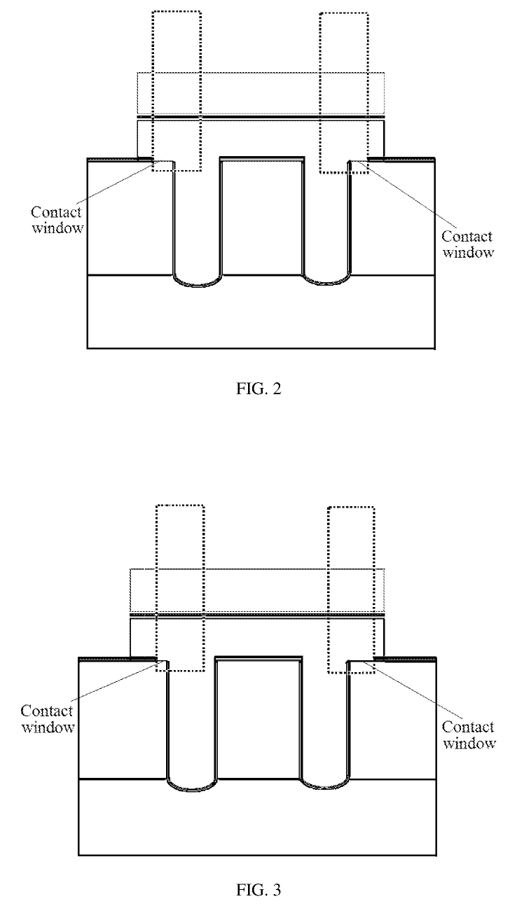

Description of reference signs:

100-semiconductor silicon substrate; 101-field oxide; 102-shallow trench isolation; 103-first region; 104-second region; 105-first active area; 109-U-shaped trench; 110-trench oxide layer; 120-semi-floating gate polysilicon; 121-gate oxide layer; 122-control gate polysilicon; 123-SIN hard mask; 124-SIN sidewall dielectric layer; 111-contact window; 125-silicon epitaxy

### DETAILED DESCRIPTION OF THE APPLICATION

The technical solutions in the present disclosure will be clearly and completely described below with reference to the drawings. Apparently, the described embodiments are some rather than all of the embodiments of the present disclosure. All other embodiments obtained by those skilled in the art based on the embodiments of the present disclosure without contributing any inventive labor shall still fall within the scope of protection of the present disclosure.

Embodiment 1

A method for manufacturing a semi-floating gate transistor includes the following steps:

S1: providing a semiconductor silicon substrate 100, where

in a first region 103 of the semiconductor silicon substrate 100, the semiconductor silicon substrate 100 is isolated by multiple strips of X-direction field oxides 101 into multiple strips of X-direction first active areas 105, and the multiple strips of X-direction field oxides 101 and the multiple strips of X-direction first active areas 105 are arranged in parallel;

an X direction is a direction parallel to a length direction of the first active areas, and a Y direction is perpendicular to the X direction;

opening the first region 103 to expose upper surfaces of the X-direction field oxides 101 and upper surfaces of the first active areas 105 in the first region 103;

performing photolithography and etching to form a U-shaped trench (U-trench) 109 in each first active area 105 along multiple pairs of Y-direction openings, where

each pair of Y-direction openings is composed of adjacent two Y-direction openings along the X direction; and

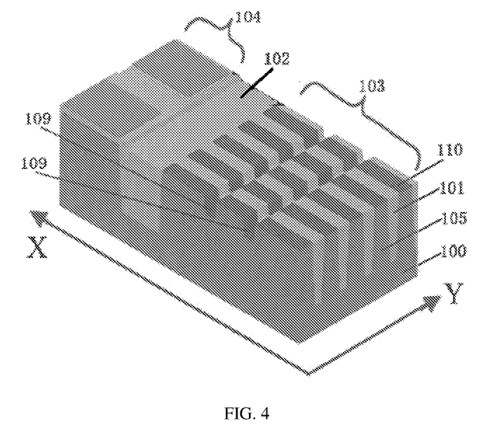

forming a trench oxide layer 110 on the upper surfaces of the first active areas 105 and surfaces of the U-shaped trenches 109, as shown in FIG. 4;

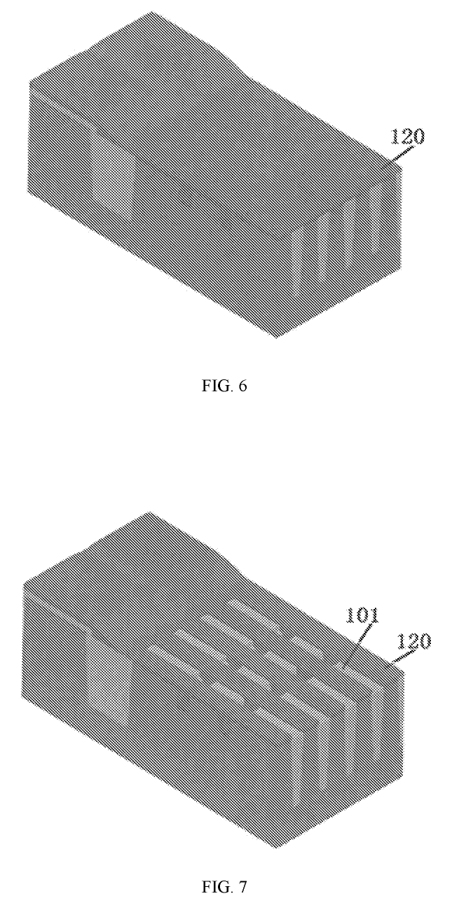

S2: depositing semi-floating gate polysilicon 120, where the U-shaped trenches 109 are filled with the semi-floating gate polysilicon 120, as shown in FIG. 6;

S3: performing photolithography and etching to remove the semi-floating gate polysilicon 120 on the X-direction field oxides 101, as shown in FIG. 7;

S4: depositing a gate oxide layer 121;

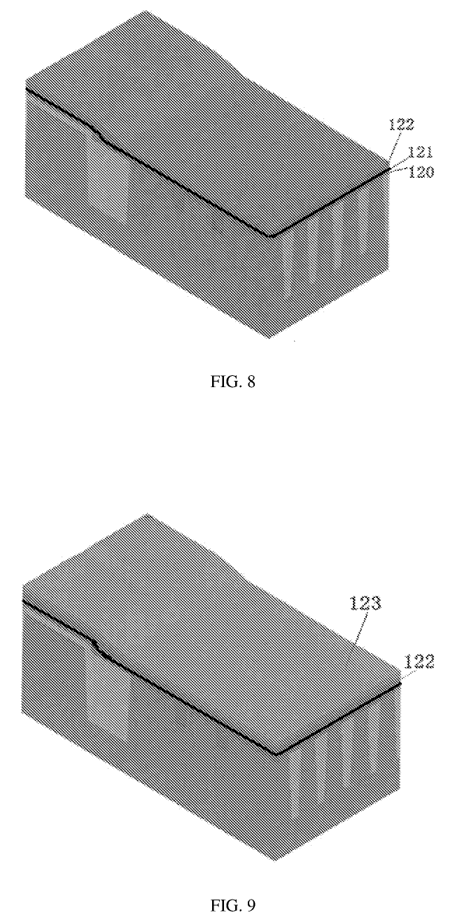

S5: depositing control gate polysilicon 122, as shown in FIG. 8;

S6: depositing an SIN hard mask 123, as shown in FIG. 9;

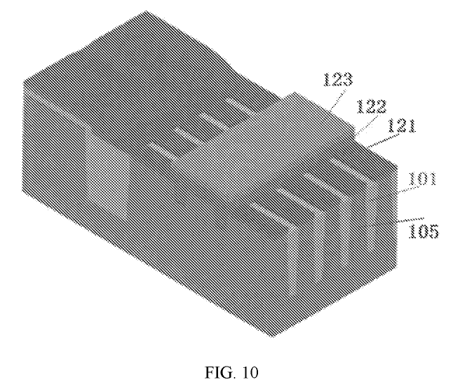

S7: performing photolithography and etching to remove the SIN hard mask 123 and the control gate polysilicon outside a set width on an X-direction outer side of each pair of Y-direction openings, stop at the gate oxide layer 121, and reserve the SIN hard mask 123 and the control gate polysilicon 122 between each pair of Y-direction openings and within the set width on the X-direction outer side thereof, as shown in FIG. 10;

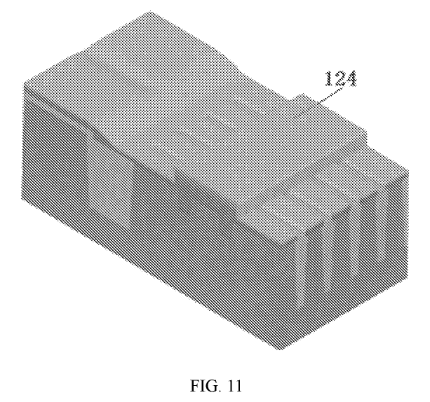

S8: depositing an SIN sidewall dielectric layer 124, as shown in FIG. 11;

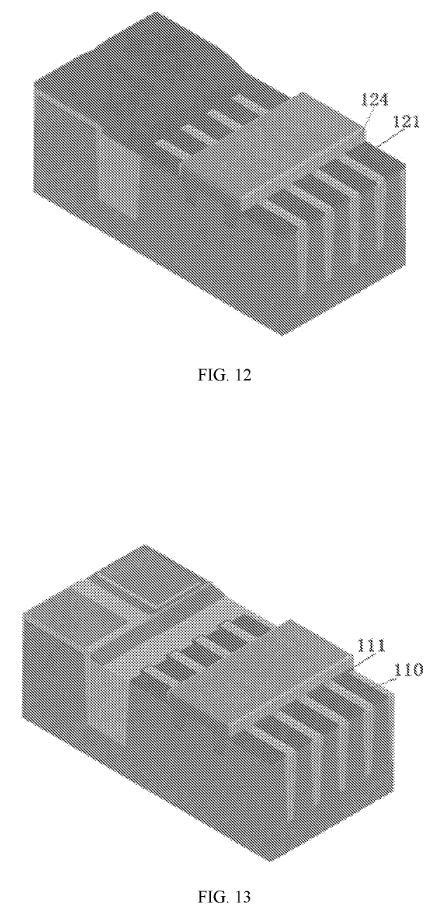

S9: etching the SIN sidewall dielectric layer 124 to remove the SIN sidewall dielectric layer 124 above the control gate polysilicon 122 corresponding to each pair of Y-direction openings, remove the SIN sidewall dielectric layer 124 above the gate oxide layer 121 on an X-direction outer side of the control gate polysilicon 122 corresponding to each pair of Y-direction openings, and form a control gate sidewall, as shown in FIG. 12;

S10: performing self-aligned etching on the trench oxide layer 110 by using the SIN hard mask 123 and the control gate sidewall as a mask to remove the gate oxide layer 121, the semi-floating gate polysilicon 120, and the trench oxide layer 110 on the X-direction outer side of the control gate polysilicon 122 corresponding to each pair of Y-direction openings, and expose the X-direction outer side of the semi-floating gate polysilicon 120 corresponding to each pair of Y-direction openings as a contact window (C-window) 111, which is a self-aligned vertical contact window (C-window), as shown in FIG. 13;

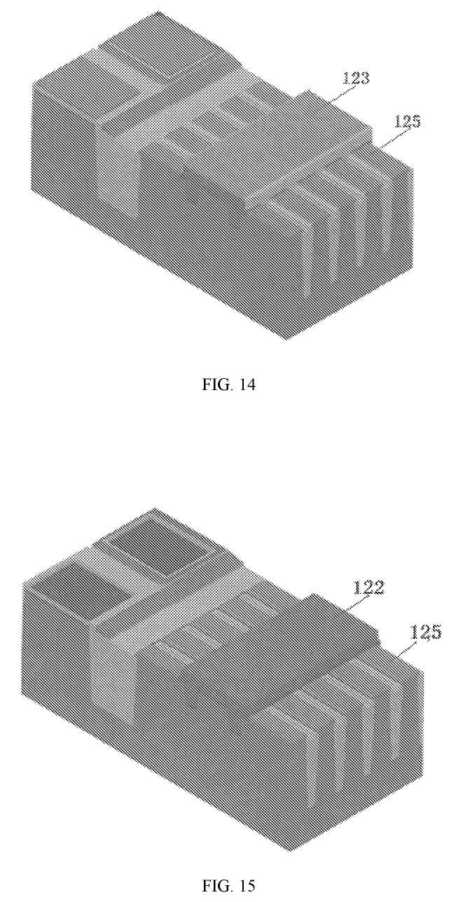

S11: growing a silicon epitaxy 125 on the upper surfaces of the exposed first active areas 105 and at the contact window 111 of the semi-floating gate polysilicon 120, as shown in FIG. 14, where the grown silicon epitaxy 125 contacts with the side surface of the semi-floating polysilicon 120 to form a PN junction, achieving the function of the contact window (C-window); and

S12: performing subsequent processes.

In the method for manufacturing the Semi-Floating Gate Transistor (SFGT) provided in embodiment 1, the photolithography and etching of the lateral contact window (C-window) are directly omitted, thus simplifying the existing two semi-floating gate polysilicon deposition processes into one; the SIN hard mask 123 is deposited on the control gate polysilicon 122, then photolithography is performed to define the control gate structure pattern, the control gate polysilicon 122 and the SIN hard mask 123 are etched, etching is stopped on the gate oxide layer 121 on the upper surface of the semi-floating gate polysilicon 120 to form the control gate structure, and then the SIN sidewall of the control gate structure is formed. Since the top of the formed control gate structure is protected by the SIN hard mask 123 and the side surface is protected by the SIN sidewall, the control gate structure is completely protected by the SIN, so that subsequently self-aligned etching can be performed on the semi-floating gate polysilicon 120 by using the SIN as a hard mask, thus forming two semi-floating gate polysilicon side notches on the X-direction outer side of each pair of Y-direction openings corresponding to the semi-floating gate polysilicon 120, which is the self-aligned vertical contact window (C-window) 111.

In the method for manufacturing the Semi-Floating Gate Transistor (SFGT) provided in embodiment 1, self-aligned etching is performed by using the mask for the photolithography of the control gate structure and using the SIN protection layer of the control gate structure to form the vertical contact window (C-window) 111，instead of the photolithography and etching of conventional lateral contact window (C-window), thus omitting one contact window (C-window) photolithography process, avoiding the formation of the asymmetric semi-floating gate device due to the deterioration of the photolithography pattern overlay (PH overlay) of the lateral contact window (C-window), and greatly improving the uniformity and the process window of the Semi-Floating Gate Transistor (SFGT). In addition, since the physical distance between the vertical contact window (C-window) 111 and the gate of the tunnel field-effect transistor (TFET) of the Semi-Floating Gate Transistor (SFGT) is significantly shortened, the tunneling efficiency is high, thus improving the charging speed of the semi-floating gate polysilicon.

Embodiment 2

Based on the method for manufacturing the Semi-Floating Gate Transistor (SFGT) provided in embodiment 1, in step S1, upper portions of the first active areas 105 undergo first-type doping and lower portions undergo second-type doping;

bottoms of the U-shaped trenches (U-trenches) 109 enter the lower portions of the first active areas 105;

in step S2, the semi-floating gate polysilicon (120) undergoes the second-type doping;

the first-type doping is N-type doping, and the second-type doping is P-type doping; or, the first-type doping is P-type doping, and the second-type doping is N-type doping.

In some embodiments, the semiconductor silicon substrate 100 further includes a second region 104; the first region 103 and the second region 104 are separated by shallow trench isolation (STI) 102; the first region 103 is used for forming a memory cell array; the second region 104 is used for forming a logic circuit.

Embodiment 3

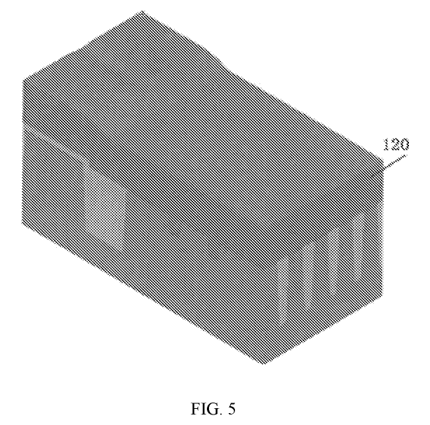

Based on the method for manufacturing the Semi-Floating Gate Transistor (SFGT) provided in embodiment 1, in step S2, the semi-floating gate polysilicon 120 is deposited firstly, as shown in FIG. 5; then blanket etching (blanket ET) is performed to thin the semi-floating gate polysilicon 120 to a required height of a top surface of a semi-floating gate polysilicon.

Embodiment 4

Based on the method for manufacturing the Semi-Floating Gate Transistor (SFGT) provided in embodiment 1, in step S7, the set width is 1 to 3 times the thickness of the trench oxide layer 110.

In some embodiments. the set width ranges from 10nm to 80nm.

Embodiment 5

Based on the method for manufacturing the Semi-Floating Gate Transistor (SFGT) provided in embodiment 1, in step S11, residual oxides on the surfaces of the first active areas 105 on the X-direction outer side of the semi-floating gate polysilicon 120 corresponding to each pair of Y-direction openings are removed firstly, and then the silicon epitaxy 125 is grown on the upper surfaces of the exposed first active areas 105 and the contact window 111 of the semi-floating gate polysilicon 120.

In some embodiments, in step S11, the upper surface of the grown silicon epitaxy 125 is in flush with the upper surface of the semi-floating gate polysilicon 120.

Embodiment 6

Based on the method for manufacturing the Semi-Floating Gate Transistor (SFGT) provided in embodiment 1, in step S12, performing subsequent processes includes removing the SIN hard mask 123 and the SIN sidewall dielectric layer 124, as shown in FIG. 15.

What are described above are only exemplary embodiments of the present disclosure, and are not intended to limit the present disclosure. Any modifications, equivalent replacements, improvements and the like made within the spirit and principle of the present disclosure shall all be included in the scope of protection of the present disclosure.

What is claimed is:

1. A method for manufacturing a semi-floating gate transistor, comprising the following steps:
S1: providing a semiconductor silicon substrate, wherein,
in a first region of the semiconductor silicon substrate, the semiconductor silicon substrate is isolated by multiple strips of X-direction field oxides into multiple strips of X-direction first active areas, and the multiple strips of X-direction field oxides and the multiple strips of X-direction first active areas are arranged in parallel;
an X direction is a direction parallel to a length direction of the X-direction first active areas, and a Y direction is perpendicular to the X direction;
opening the first region to expose upper surfaces of the X-direction field oxides and upper surfaces of the X-direction first active areas in the first region;
performing photolithography and etching to form a U-shaped trench in each X-direction first active area along a plurality of pairs of Y-direction openings, wherein each pair of Y-direction openings is composed of an adjacent two Y-direction openings along the X direction; and
forming a trench oxide layer on the upper surfaces of the X-direction first active areas and surfaces of the U-shaped trenches;
S2: depositing semi-floating gate polysilicon, wherein the U-shaped trenches are filled with the semi-floating gate polysilicon;
S3: performing photolithography and etching to remove semi-floating gate polysilicon on the X-direction field oxides;
S4: depositing a gate oxide layer;
S5: depositing control gate polysilicon;
S6: depositing an SIN hard mask;
S7: performing photolithography and etching to remove the SIN hard mask and the control gate polysilicon outside a set width on an X-direction outer side of each pair of Y-direction openings, stop at the gate oxide layer, and reserve the SIN hard mask and the control gate polysilicon between each pair of Y-direction openings and within the set width on the X-direction outer side thereof;
S8: depositing an SIN sidewall dielectric layer;
S9: etching the SIN sidewall dielectric layer to remove the SIN sidewall dielectric layer above the control gate polysilicon corresponding to each pair of Y-direction openings, remove the SIN sidewall dielectric layer above the gate oxide layer on an X-direction outer side of the control gate polysilicon corresponding to each pair of Y-direction openings, and form a control gate sidewall;
S10: performing self-aligned etching on the trench oxide layer by using the SIN hard mask and the control gate sidewall as a mask to remove the gate oxide layer, the semi-floating gate polysilicon, and the trench oxide layer on the X-direction outer side of the control gate polysilicon corresponding to each pair of Y-direction openings, and expose the X-direction outer side of the semi-floating gate polysilicon corresponding to each pair of Y-direction openings as a contact window;
S11: growing a silicon epitaxy on the upper surfaces of exposed X-direction first active areas and at the contact window of the semi-floating gate polysilicon; and
S12: performing subsequent processes.

2. The method for manufacturing the semi-floating gate transistor according to claim 1, wherein, in step S12, the performing the subsequent processes comprises removing the SIN hard mask and the SIN sidewall dielectric layer.

3. The method for manufacturing the semi-floating gate transistor according to claim 1, wherein the semiconductor silicon substrate further comprises a second region, the first region and the second region are separated by shallow trench isolation, the first region is used for forming a memory cell array, and the second region is used for forming a logic circuit.

4. The method for manufacturing the semi-floating gate transistor according to claim 1, wherein, in step S2, the semi-floating gate polysilicon is deposited firstly, and then blanket etching is performed to thin the semi-floating gate polysilicon to a required height of a top surface of the semi-floating gate polysilicon.

5. The method for manufacturing the semi-floating gate transistor according to claim 1, wherein, in step S11, residual oxides on the surfaces of the X-direction first active areas on the X-direction outer side of the semi-floating gate polysilicon corresponding to each pair of Y-direction openings are removed firstly, and then the silicon epitaxy is grown on the upper surfaces of the exposed X-direction first active areas and the contact window of the semi-floating gate polysilicon.

6. The method for manufacturing the semi-floating gate transistor according to claim 1, wherein, in step S11, an upper surface of the grown silicon epitaxy is in flush with an upper surface of the semi-floating gate polysilicon.

7. The method for manufacturing the semi-floating gate transistor according to claim 1, wherein the set width is 1 to 3 times a thickness of the trench oxide layer.

8. The method for manufacturing the semi-floating gate transistor according to claim 7, wherein the set width ranges from 10nm to 80nm.

9. The method for manufacturing the semi-floating gate transistor according to claim 1, wherein, in step S1, upper portions of the X-direction first active areas undergo a first-type doping and lower portions undergo a second-type doping;
bottoms of the U-shaped trenches enter the lower portions of the X-direction first active areas; and
in step S2, the semi-floating gate polysilicon undergoes the second-type doping,
wherein the first-type doping is an N-type doping, and the second-type doping is a P-type doping; or, the first-type doping is the P-type doping, and the second-type doping is the N-type doping.
